(19) United States
(12) Patent Application Publication
(10) Pub. No.: US 2025/0349737 A1
(43) Pub. Date: Nov. 13, 2025

(54) PHOTOLITHOGRAPHY METHOD AND STRUCTURES THEREOF

(71) Applicant: Taiwan Semiconductor Manufacturing Company, Ltd., Hsinchu (TW)

(72) Inventors: Hao Chu Liao, Hsinchu County (TW); Wei Tse Hsu, Hsinchu County (TW); Chen-Yen Kao, Hsinchu City (TW)

(21) Appl. No.: 19/274,065

(22) Filed: Jul. 18, 2025

Related U.S. Application Data
(63) Continuation of application No. 18/421,399, filed on Jan. 24, 2024.
(60) Provisional application No. 63/583,504, filed on Sep. 18, 2023.

(51) Int. Cl. H01L 23/544; G03F 1/42; G03F 7/00; G03F 9/00

(52) U.S. Cl. CPC H01L 23/544; G03F 7/70633; G03F 9/7076; G03F 9/7084; G03F 1/42; H01L 2223/54426

(57) ABSTRACT

A semiconductor device includes a substrate having a plurality of chip regions. In some embodiments, the semiconductor device further includes a plurality of scribe lines interposing the plurality of chip regions. In some examples, the semiconductor device further includes a first plurality of alignment mark regions distributed within the plurality of scribe lines. In some embodiments, the semiconductor device further includes a second plurality of alignment mark regions distributed within each of the plurality of chip regions.

### CROSS-REFERENCE TO RELATED APPLICATIONS

This application is a continuation of U.S. patent application Ser. No. 18/421,399, filed Jan. 24, 2024, which claims benefit of U.S. Provisional Patent Application Ser. No. 63/583,504, filed Sep. 18, 2023, the entire disclosures of which are incorporated by reference herein.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

As merely one example, and as part of a photolithography process, overlay includes an ability of a photolithography tool to align and print layers of a semiconductor IC accurately on top of each other. With the increasing complexity and number of layers used to form advanced ICs, overlay remains a critical manufacturing issue. Overlay raw data may be described as a shifted distance (or offset distance) between an ideal (or target) position and an actual position of an alignment mark patterned on a substrate. Based on the determined offset distance, a photolithography tool may be positionally adjusted (or offset) in accordance with the offset distance to minimize overlay errors between successively patterned layers. If the determined offset distance is not accurate, the positional adjustment of the photolithography tool will also be inaccurate. Thus, existing techniques have not proved entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a top view of a semiconductor substrate, in accordance with some embodiments;

FIG. 2 provides an enlarged view of a portion of the substrate of FIG. 1, in accordance with some embodiments;

FIG. 3 provides an enlarged view of an exemplary alignment mark region, according to some embodiments;

FIGS. 4A, 4B, 4C, 4D, 4E, 4F, and 4G illustrate exemplary types of patterns that may be used to provide an alignment mark within a cell of an alignment mark region, in accordance with some embodiments;

FIG. 5 illustrates a functional flow of an IC manufacturing system including a lithography correction system, in accordance with some embodiments;

FIG. 6 provides a schematic view of a lithography system, in accordance with some embodiments;

FIG. 7 is a flow chart of a method for reducing overlay error, according to one or more aspects of the present disclosure; and

FIG. 8 is a schematic view illustrating an embodiment of a computer system.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Additionally, throughout the present disclosure, the terms “mask”, “photomask”, and “reticle” may be used interchangeably to refer to a lithographic template, such as an EUV mask.

In a photolithography process, overlay includes an ability of a photolithography tool to align and print layers of a semiconductor IC accurately on top of each other. As an ever-increasing complexity of patterns, and a large number of layers, are used to form advanced ICs, overlay remains a critical manufacturing issue. Overlay raw data may be described as a shifted distance (or offset distance), which may include a measured distance, between an ideal (or target) position and an actual position of an alignment mark patterned on a substrate. Based on the determined offset distance, a photolithography tool may be positionally adjusted (or offset) in accordance with the offset distance to minimize overlay errors between successively patterned layers. If the determined offset distance is not accurate, the positional adjustment of the photolithography tool will also be inaccurate. In some cases, errors in the determined offset distance may happen as a result of an undesirably low number of alignment marks that are present across a wafer. The low number of alignment marks will result in a limited set of overlay raw data. As such, much overlay error information may be lost and subsequent lithography processes may have poor overlay performance (e.g., increased overlay error) due to inaccuracies in the positional adjustment of the photolithography tool. As a result, existing techniques for reducing overlay error have not proved entirely satisfactory in all respects.

Embodiments of the present disclosure offer advantages over the existing art, though it is understood that other embodiments may offer different advantages, not all advantages are necessarily discussed herein, and no particular advantage is required for all embodiments. For example, embodiments of the present disclosure provide a semiconductor device, and related method, for increasing an amount of overlay raw data that is retrieved, thereby mitigating loss of overlay error information, and reducing overlay error by ensuring that the positional adjustment of the photolithography tool is more accurate. In various embodiments, the increased amount of overlay raw data is provided by the use of a high density of alignment marks. In particular, and in various embodiments, the alignment marks are distributed both in wafer scribe lines (e.g., between chips) and within individual chips themselves. In some embodiments, alignment marks are positioned at corners of the scribe lines between chips, as well as being positioned according to a regular distribution (e.g., such as every 4 mm in both X- and Y-directions) along the scribe lines. Further, in various examples, a plurality of alignment marks (e.g., at least 4) are positioned within an area of each chip, the plurality of alignment marks being uniformly distributed throughout the area of each chip. To be sure, in various embodiments, the exact positions and/or number of the alignment marks within the chips may vary based on a particular layer being patterned. By implementing the techniques described herein, overlay error may be reduced by around 50%, in comparison to at least some existing processes.

In various embodiments, different types of cells (e.g., such as including squares, rectangles, lines, arrays thereof, or combinations thereof) may be used to define each alignment mark of the plurality of alignment marks. For each type of cell, a duty ratio may be defined as a pattern width divided by a pattern spacing (W/S). In some embodiments, the duty ratio may be in a range from about 0.5 to about 3. Also, the X- and Y-directions used to determine the duty ratio may vary for different embodiments. In some examples, the type of cell used in-chip versus in the scribe lines may be the same or different. Inside each cell, the pattern may generally include a repeating array that follows a defined duty ratio. Also, in some cases, a dummy pattern may be provided (e.g., at a distance of at least 1 micron from the cell) to prevent pattern density loading. In some embodiments, a total number of alignment marks is between about 950 and about 1000. Those skilled in the art will recognize other benefits and advantages of the methods and devices as described herein, and the embodiments described are not meant to be limiting beyond what is specifically recited in the claims that follow.

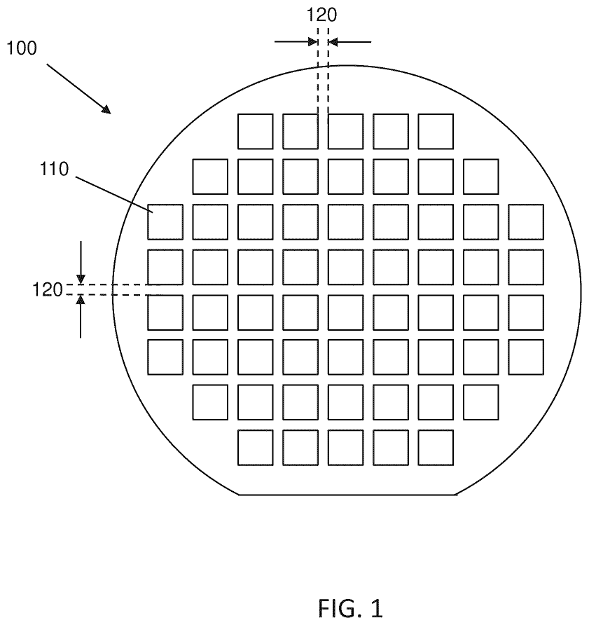

Referring now to FIG. 1, illustrated therein is a top view of a semiconductor substrate 100 (or substrate 100). The substrate 100 includes a plurality of chip regions 110 within which semiconductor devices and/or circuits may be formed. As shown, the chip regions 110 are isolated from each other by scribe lines 120 disposed between adjacent ones of the plurality of chip regions 110. The scribe lines 120 define regions where the substrate 100 will be cut, after completion of a device and/or circuit fabrication process, so that the plurality of chip regions 110 may be separated into a plurality of discrete chips.

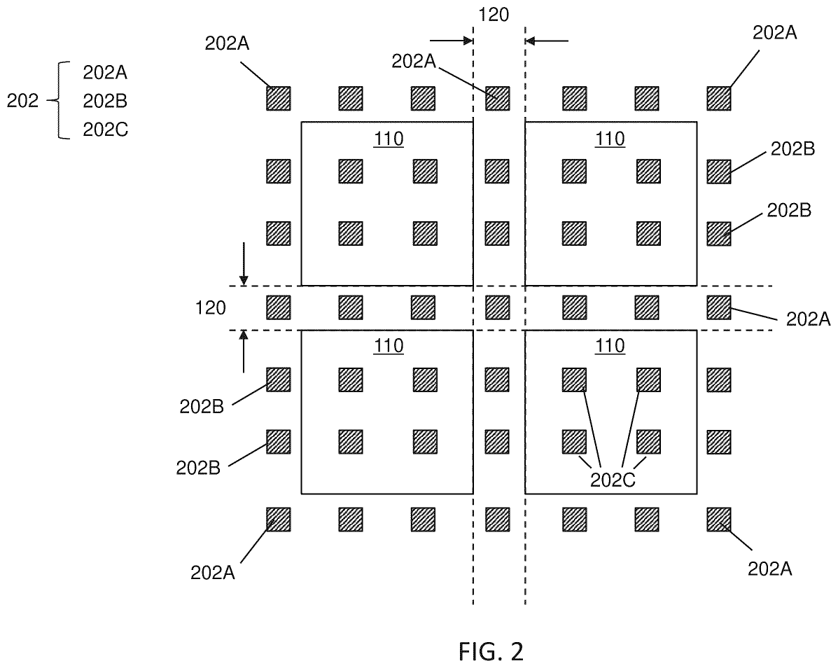

FIG. 2 provides an enlarged view of a portion of the substrate 100 of FIG. 1, which more clearly illustrates some of the plurality of chip regions 110, as well as the scribe lines 120 surrounding and/or interposing the chip regions 110. FIG. 2 also illustrates a plurality of alignment mark regions 202, where the plurality of alignment mark regions 202 may include alignment mark regions 202A located at one or more exposure field corners and within the scribe lines 120, alignment mark regions 202B located between adjacent chip regions 110 and within the scribe lines 120, and alignment mark regions 202C located within each of the plurality of chip regions 110.

The plurality of alignment mark regions 202 may be used to align upper and lower ones of a plurality of material layers that are formed on the substrate 100 when these material layers are patterned. Stated another way, the plurality of alignment mark regions 202 may be used to ensure that features in a given layer are precisely aligned to features in one or more underlying layers. By way of example, during IC manufacturing, a plurality of material layers may be patterned by repeating a photolithography process and an etching process. For instance, a photoresist (resist) layer may be formed on a material layer that is to be patterned, and the resist layer may be exposed using a lithography system according to a pattern (e.g., defined by a photomask) and developed to provide a patterned resist layer. Prior to exposure, alignment marks (e.g., such as within alignment regions 202) on the photomask may be aligned to corresponding alignment marks on or within the material layer. After development of the exposed pattern, an after develop inspection (ADI) may be performed to provide overlay data. Thereafter, an etching process may be performed so that the pattern provided by the patterned resist layer is transferred to the underlying material layer. After the etching process, an after etch inspection (AEI) may be performed to provide additional overlay data such as etch-induced overlay variances. In various examples, the ADI and the AEI processes may be performed using metrology tools that employ image-based overlay (IBO) methods, diffraction-based overlay (DBO) methods, or a combination thereof. Based on the overlay data collected (e.g., from ADI and AEI), adjustments may be made to the lithography system, and in some cases to one or more etching systems, to improve (reduce) overlay error. In some examples, the adjustments made to the lithography system may correct for translation errors, rotational errors, and/or higher-order errors. Thereafter, patterning and etching of additional material layers may be similarly performed on some or all of subsequent material layers that are sequentially stacked on the patterned underlying material layer. Further, inspection (e.g., to collect overlay data) and adjustments (e.g., to the lithography system) may be performed with respect to formation of each of the subsequent material layers, as needed.

Still referring to FIG. 2 and the alignment mark regions 202, the alignment mark regions 202A and 202B may be distributed at regular intervals along the scribe lines 120. As one example, the alignment mark regions 202 in the scribe lines 120 may be spaced at 4 mm intervals in both X- and Y-directions. In other examples, the alignment mark regions 202 in the scribe lines 120 may be spaced at other intervals such as 1 mm, 2 mm, 2.5 mm, 5 mm, or other suitable intervals in both the X- and Y-directions. Further, a plurality of alignment mark regions 202C are located within each of the plurality of chip regions 110. In some embodiments, at least four alignment mark regions 202C are located within each of the plurality of chip regions 110. The alignment mark regions 202C, in various cases, may be uniformly distributed throughout an area of each chip region of the plurality of chip regions 110. For example, for the case of four alignment mark regions 202C, one alignment mark region 202C may be located within each quadrant of each of the chip regions 110. To be sure, in some embodiments, the exact positions and/or number of the alignment mark regions 202C within the chip regions 110 may vary based on a particular layer being patterned. For instance, while four alignment mark regions 202C are shown within each chip region 110 in the example of FIG. 2, another number of alignment mark regions 202C may be used without departing from the scope of the present disclosure. In some cases, a greater number of alignment mark regions 202C may be included within each chip region 110 when a critical layer, as opposed to a non-critical layer, is being patterned. Thus, in some embodiments, two or more alignment mark regions 202C may be located within one or more quadrants of each of the chip regions 110. More generally, while a particular number of alignment mark regions 202 are shown as being formed within the scribe lines 120 (alignment mark regions 202A, 202B) and within the chip regions 110 (alignment mark regions 202C), these examples are not meant to be limiting, and a different number and/or distribution of alignment mark regions 202A, 202B, 202C may be used without departing from the scope of the present disclosure.

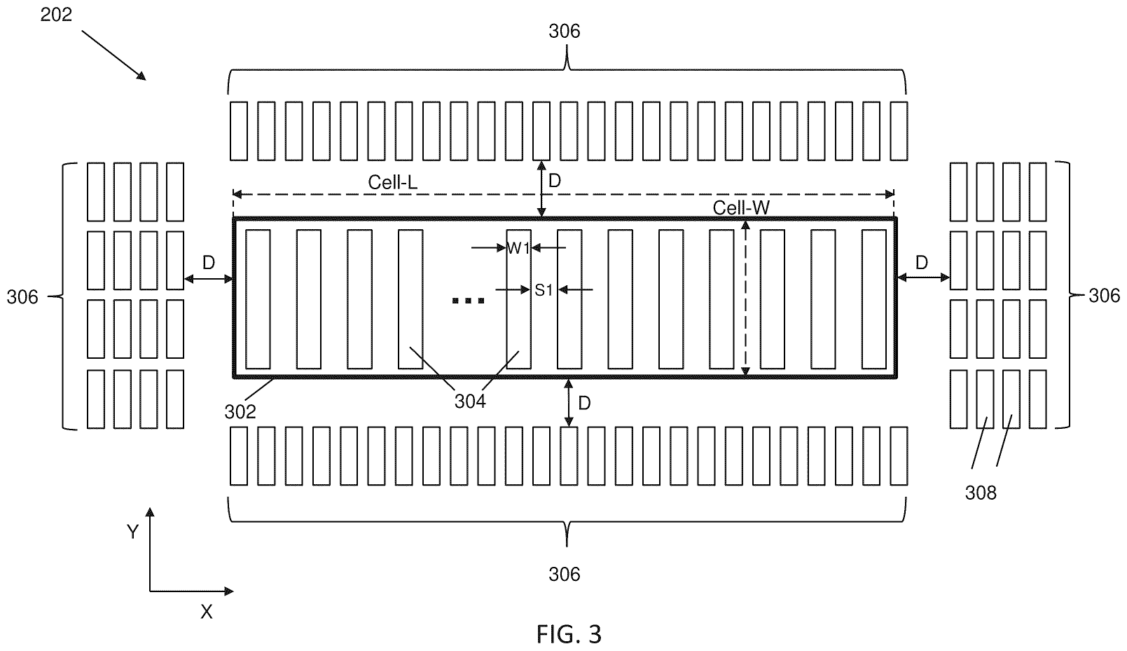

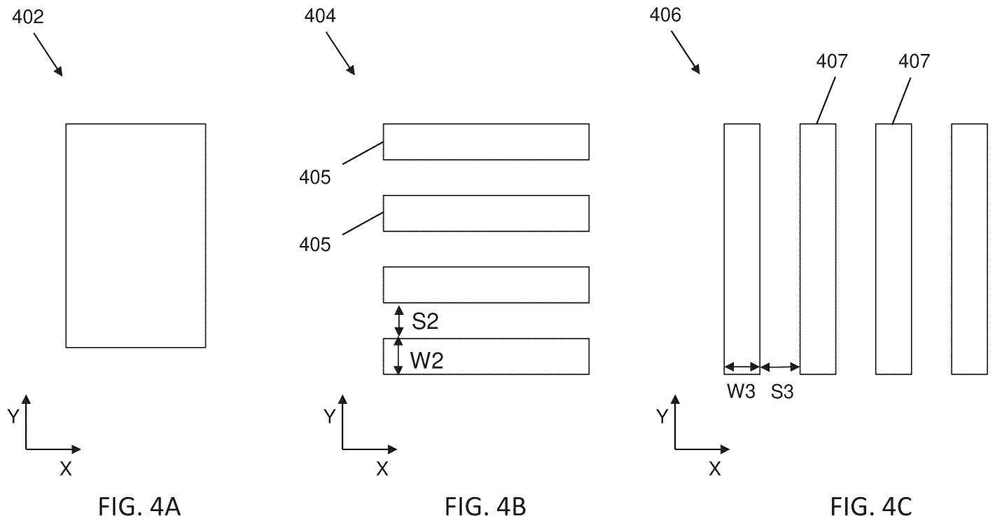

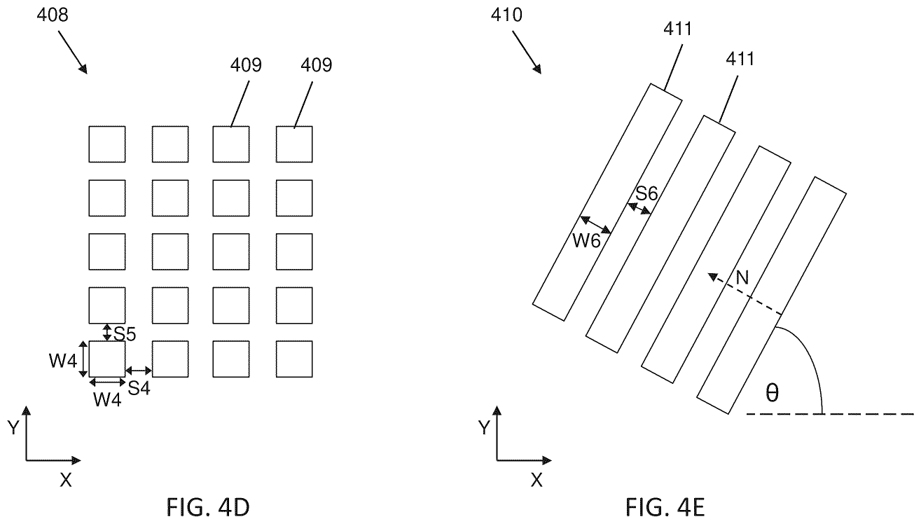

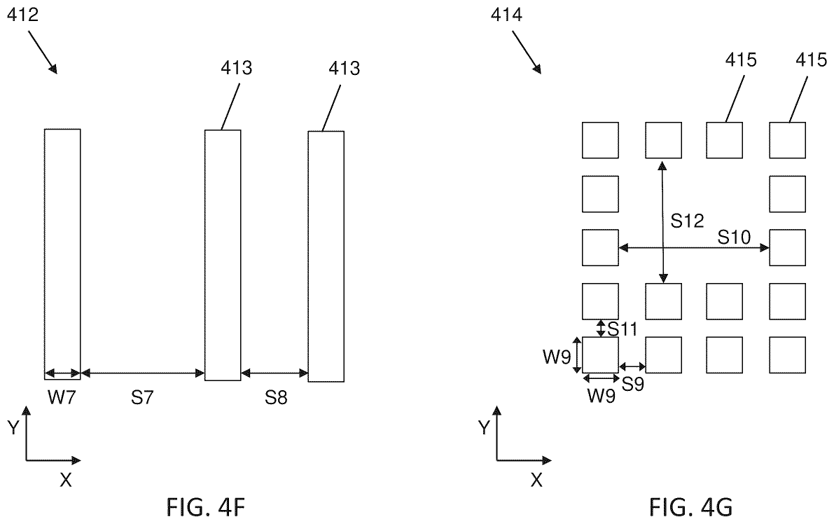

Referring now to FIG. 3, illustrated therein is an enlarged view of an exemplary alignment mark region 202. The exemplary alignment mark region 202 of FIG. 3 may be used to provide the alignment mark region 202A, the alignment mark region 202B, and/or the alignment mark region 202C. As shown, the alignment mark region 202 includes a cell 302 that includes an alignment mark for the alignment mark region 202. In some embodiments, the cell 302 has a cell length ‘Cell-L’ in a range from about 200-250 microns and a cell width ‘Cell-W’ in a range from about 38-100 microns. In the example of FIG. 3, the cell 302 includes an array of rectangular patterns 304. However, more generally, the cell 302 may include any of a plurality of different types of cells having different types of patterns (e.g., such as including squares, rectangles, lines, arrays thereof, or combinations thereof), some of which are discussed in more detail below with reference to FIGS. 4A-4G. It is noted that in various cases, the type of cell (and thus the type of pattern) used to provide the alignment mark for the alignment mark regions 202A, 202B in the scribe lines 120 may be the same as, or different from, the type of cell (and thus the type of pattern) used to provide the alignment mark for the alignment mark region 202C in the chip regions 110.

Further, in the present example, the array of rectangular patterns 304 has a duty ratio (along an X-direction) defined as a width ‘W1’ of an individual rectangular pattern 304 divided by a pattern spacing ‘S1’ (W1/S1). In various embodiments, the duty ratio W1/S1 may be in a range from about 0.5 to about 3. In some embodiments, a dummy pattern 306 is also provided adjacent one or more sides of the cell 302. Thus, by way of example, the exemplary alignment mark region 202 may include both the cell 302, which includes the alignment mark for the alignment mark region 202, as well as the dummy pattern 306. As shown, the dummy pattern 306 may include an array of features 308 such as an array of rectangular features, square features, circular features, line features, combinations thereof, or other suitable features. In addition, and to prevent pattern density loading, the dummy pattern 306 may be spaced a distance ‘D’ from a respective side of the cell 302 to which the dummy pattern 306 is adjacent. In some embodiments, the distance ‘D’ is equal to or greater than 1 micron.

FIGS. 4A-4G illustrate exemplary types of patterns that may be used to provide an alignment mark within a cell (e.g., such as the cell 302) of an alignment mark region (e.g., such as the alignment mark regions 202A, 202B, 202C). The example of FIG. 4A illustrates a first pattern type 402 that can be used to provide a first cell type. In particular, the first pattern type 402 does not have a duty ratio. Stated another way, the first pattern type 402 may include a single pattern that substantially fills the cell (e.g., such as the cell 302). The example of FIG. 4B illustrates a second pattern type 404 that can be used to provide a second cell type. In particular, the second pattern type 404 includes an array of rectangular patterns 405. In some embodiments, the array of rectangular patterns 405 has a duty ratio (along a Y-direction) defined as a width ‘W2’ of an individual rectangular pattern 405 divided by a pattern spacing ‘S2’ (W2/S2). In various embodiments, the duty ratio W2/S2 may be in a range from about 0.5 to about 3. In some cases, the duty ratio of the array of the rectangular patterns 405 may be constant along the Y-direction of the cell (e.g., when the width ‘W2’ and the spacing ‘S2’ are constant). However, in some embodiments, the duty ratio of the array of the rectangular patterns 405 may vary along the Y-direction of the cell (e.g., when the width ‘W2’ and/or the spacing ‘S2’ vary along the Y-direction).

The example of FIG. 4C illustrates a third pattern type 406 that can be used to provide a third cell type. In particular, the third pattern type 406 includes an array of rectangular patterns 407. In some embodiments, the array of rectangular patterns 407 has a duty ratio (along an X-direction) defined as a width ‘W3’ of an individual rectangular pattern 407 divided by a pattern spacing ‘S3’ (W3/S3). In various embodiments, the duty ratio W3/S3 may be in a range from about 0.5 to about 3. In an embodiment, the third pattern type 406 may be substantially the same as the array of rectangular patterns 304 in the cell 302 of FIG. 3. In some cases, the duty ratio of the array of the rectangular patterns 407 may be constant along the X-direction of the cell (e.g., when the width ‘W3’ and the spacing ‘S3’ are constant). However, in some embodiments, the duty ratio of the array of the rectangular patterns 407 may vary along the X-direction of the cell (e.g., when the width ‘W3’ and/or the spacing ‘S3’ vary along the X-direction).

The example of FIG. 4D illustrates a fourth pattern type 408 that can be used to provide a fourth cell type. In particular, the fourth pattern type 408 includes an array of square patterns 409. In some embodiments, the array of square patterns 409 has a first duty ratio (along an X-direction) defined as a width ‘W4’ of an individual square pattern 409 divided by a pattern spacing in the X-direction ‘S4’ (W4/S4) and a second duty ratio (along a Y-direction) defined as the width ‘W4’ of an individual square pattern 409 divided by a pattern spacing in the Y-direction ‘S5’ (W4/S5). In the present example, the spacing in the Y-direction ‘S5’ is less than the spacing in the X-direction ‘S4’, resulting in the second duty ratio (along the Y-direction) being greater than the first duty ratio (along the X-direction). In other examples, the first duty ratio (along the X-direction) may be greater than the second duty ratio (along the Y-direction), or the first and second duty ratios may be the same. Generally, the duty ratio may be defined independently for each direction (e.g., such as the X-direction and the Y-direction). Even though the duty ratios may vary, in various embodiments, each of the first duty ratio W4/S4 and the second duty ratio W4/S5 may be in a range from about 0.5 to about 3. In some cases, the first duty ratio and the second duty ratio may be constant along respective X- and Y-directions of the cell (e.g., when the widths and spacings in the respective X- and Y-directions are constant). However, in some embodiments, the first duty ratio and the second duty ratio may vary along respective X- and Y-directions of the cell (e.g., when the widths and/or spacings in the respective X- and/or Y-directions vary).

The example of FIG. 4E illustrates a fifth pattern type 410 that can be used to provide a fifth cell type. In particular, the fifth pattern type 410 includes an array of rectangular patterns 411. In some respects, the fifth pattern type 410 is similar to the second pattern type 404 and the third pattern type 406, insofar as they each include an array of rectangular patterns. However, as shown, the fifth pattern type 410 is rotated by an angle θ with respect to the X-direction. Thus, in some embodiments, the array of rectangular patterns 411 has a duty ratio (along a direction N that is normal to a plane parallel to the angle θ) defined as a width ‘W6’ of an individual rectangular pattern 411 divided by a pattern spacing ‘S6’ (W6/S6). In various embodiments, the duty ratio W6/S6 may be in a range from about 0.5 to about 3. In some cases, the duty ratio of the array of the rectangular patterns 411 may be constant along the direction N of the cell (e.g., when the width ‘W6’ and the spacing ‘S6’ are constant). However, in some embodiments, the duty ratio of the array of the rectangular patterns 411 may vary along the direction N of the cell (e.g., when the width ‘W6’ and/or the spacing ‘S6’ vary along the direction N).

The example of FIG. 4F illustrates a sixth pattern type 412 that can be used to provide a sixth cell type. In particular, the sixth pattern type 412 includes an array of rectangular patterns 413. The sixth pattern type 412, in some embodiments, is similar to the third pattern type 406, discussed above. However, the sixth pattern type 412 has a varying duty ratio as a result of a varying pattern spacing. To be sure, in other cases, the varying duty ratio may be a result of a varying pattern width. In the example shown, the array of rectangular patterns 413 has a first duty ratio (along an X-direction and for a first part of the sixth pattern type 412) defined as a width ‘W7’ of an individual rectangular pattern 413 divided by a first pattern spacing ‘S7’ (W7/S7) and a second duty ratio (along the X-direction and for a second part of the sixth pattern type 412) defined as the width ‘W7’ of an individual rectangular pattern 413 divided by a second pattern spacing ‘S8’ (W7/S8). In the present example, the first pattern spacing ‘S7’ is greater than the second pattern spacing ‘S8’, resulting in the second duty ratio being greater than the first duty ratio. In other examples, such as when the second pattern spacing ‘S8’ is greater than the first pattern spacing ‘S7’, the first duty ratio may be greater than the second duty ratio. In still other cases, alternating ones of the first duty ratio or the second duty ratio may greater than the other (optionally, in a periodic manner), along an entirety of the X-direction of the sixth pattern type 412. Although the duty ratio may vary, each of the first duty ratio W7/S7 and the second duty ratio W7/S8 may be in a range from about 0.5 to about 3.

The example of FIG. 4G illustrates a seventh pattern type 414 that can be used to provide a seventh cell type. In particular, the seventh pattern type 414 includes an array of square patterns 415. The seventh pattern type 414, in some embodiments, is similar to the fourth pattern type 408, discussed above. However, the seventh pattern type 414 has a varying duty ratio as a result of a varying pattern spacing. To be sure, in other cases, the varying duty ratio may be a result of a varying pattern width. In the example shown, the array of square patterns 415 has a first duty ratio (along an X-direction and in a first region of the seventh pattern type 414) defined as a width ‘W9’ of an individual square pattern 415 divided by a first pattern spacing in the X-direction ‘S9’ (W9/S9), a second duty ratio (along the X-direction and in a second region of the seventh pattern type 414) defined as the width ‘W9’ of the individual square pattern 415 divided by a second pattern spacing in the X-direction ‘S10’ (W9/S10), a third duty ratio (along a Y-direction and in the first region of the seventh pattern type 414) defined as the width ‘W4’ of an individual square pattern 415 divided by a first pattern spacing in the Y-direction ‘S11’ (W4/S11), and a fourth duty ratio (along the Y-direction and in the second region of the seventh pattern type 414) defined as the width ‘W4’ of the individual square pattern 415 divided by a second pattern spacing in the Y-direction ‘S12’ (W4/S12). In some cases, the second region of the seventh pattern type 414 may be described as having a gap without any of the individual square patterns 415, and resulting in the second pattern spacings in the X-direction and the Y-direction. In the present example, the first pattern spacing in the Y-direction ‘S11’ is less than the first pattern spacing in the X-direction ‘S9’, resulting in the third duty ratio W4/S11 (along the Y-direction) being greater than the first duty ratio W9/S9 (along the X-direction). In other examples, the first duty ratio W9/S9 (along the X-direction) may be greater than the third duty ratio W4/S11 (along the Y-direction), or the first and third duty ratios may be the same. Further, the second pattern spacing in the X-direction ‘S10’ is greater than the first pattern spacing in the X-direction ‘S9’, resulting in the first duty ratio W9/S9 (along the X-direction) being greater than the second duty ratio W9/S10 (along the X-direction). In addition, the second pattern spacing in the Y-direction ‘S12’ is greater than the first pattern spacing in the Y-direction ‘S11’, resulting in the third duty ratio W4/S11 (along the Y-direction) being greater than the fourth duty ratio W4/S12 (along the Y-direction). Generally, and as discussed with respect to the fourth pattern type 408, the duty ratio may be defined independently for each direction (e.g., such as the X-direction and the Y-direction). Although the duty ratios may vary, each of the first duty ratio W9/S9, the second duty ratio W9/S10, the third duty ratio W4/S11, and the fourth duty ratio W4/S12 may be in a range from about 0.5 to about 3.

While some exemplary types of patterns that may be used to provide an alignment mark within a cell (e.g., such as the cell 302) of an alignment mark region (e.g., such as the alignment mark regions 202A, 202B, 202C) have been discussed with reference to FIGS. 4A-4G, these examples are merely illustrative, and are not meant to be limiting. It will be understood that other types of patterns, apart from and/or in addition to those described above, may be equally used without departing from the scope of the present disclosure. Further, in various embodiments, combinations of two or more pattern types may be combined within a particular cell (e.g., such as the cell 302) to provide the alignment mark of the alignment mark region (e.g., such as the alignment mark regions 202A, 202B, 202C).

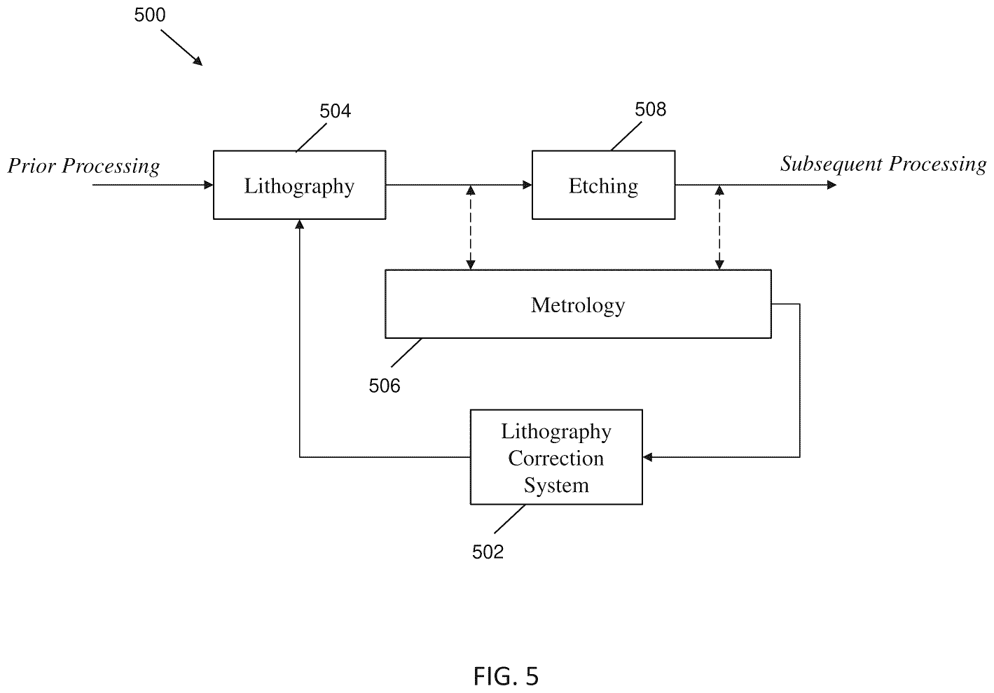

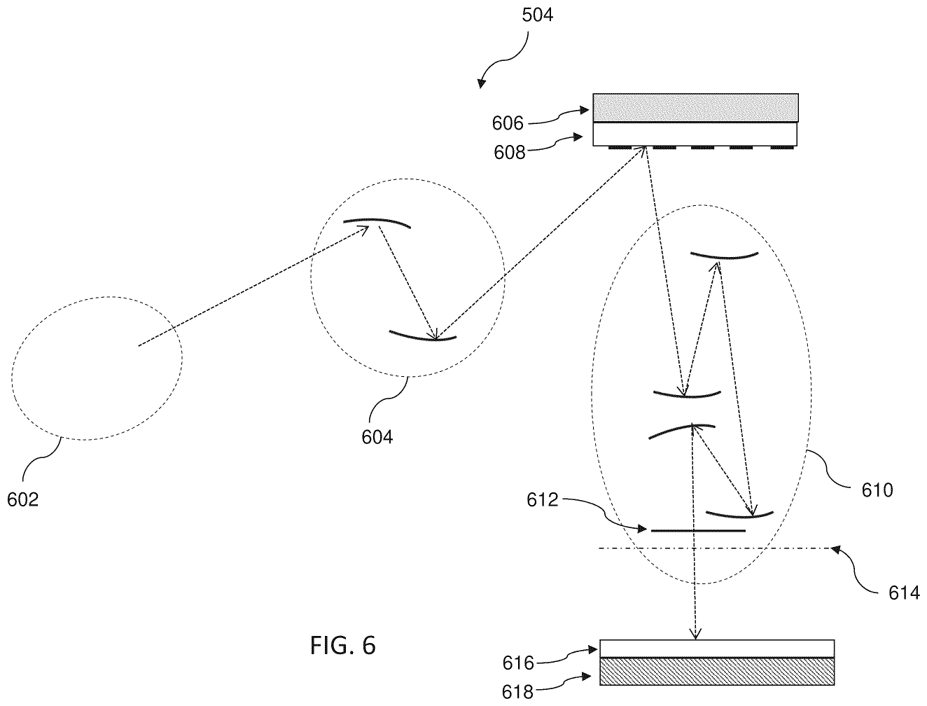

Referring now to FIG. 5, illustrated therein is a functional flow of an IC manufacturing system 500 including a lithography correction system 502. In the example shown, a substrate (e.g., such as the substrate 100) is provided to a lithography system 504, in some cases after prior processing has been performed on the substrate. A schematic view of the lithography system 504 is provided in FIG. 6, in accordance with some embodiments.

The lithography system 504 may also be generically referred to as a scanner that is operable to perform lithographic processes including exposure with a respective radiation source and in a particular exposure mode. In at least some of the present embodiments, the lithography system 504 includes an extreme ultraviolet (EUV) lithography system designed to expose a resist layer by EUV light. Inasmuch, in various embodiments, the resist layer includes a material sensitive to the EUV light (e.g., an EUV resist). The lithography system 504 includes a plurality of subsystems such as a radiation source 602, an illuminator 604, a mask stage 606 configured to receive a mask 608, projection optics 610, and a substrate stage 618 configured to receive a substrate 616 (and which may include the substrate 100). A general description of the operation of the lithography system 504 may be given as follows: EUV light from the radiation source 602 is directed toward the illuminator 604 (which includes a set of reflective mirrors) and projected onto the reflective mask 608. A reflected mask image is directed toward the projection optics 610, which focuses the EUV light and projects the EUV light onto the substrate 616 to expose an EUV resist layer deposited thereupon. Additionally, in various examples, each subsystem of the lithography system 504 may be housed in, and thus operate within, a high-vacuum environment, for example, to reduce atmospheric absorption of EUV light.

In the embodiments described herein, the radiation source 602 may be used to generate the EUV light. In some embodiments, the radiation source 602 includes a plasma source, such as for example, a discharge produced plasma (DPP) or a laser produced plasma (LPP). In some examples, the EUV light may include light having a wavelength ranging from about 1 nm to about 100 nm. In one particular example, the radiation source 602 generates EUV light with a wavelength centered at about 13.5 nm. Accordingly, the radiation source 602 may also be referred to as an EUV radiation source 602. In some embodiments, the radiation source 602 also includes a collector, which may be used to collect EUV light generated from the plasma source and to direct the EUV light toward imaging optics such as the illuminator 604.

As described above, light from the radiation source 602 is directed toward the illuminator 604. In some embodiments, the illuminator 604 may include reflective optics (e.g., for the EUV lithography system 504), such as a single mirror or a mirror system having multiple mirrors in order to direct light from the radiation source 602 onto the mask stage 606, and particularly to the mask 608 secured on the mask stage 606. In some examples, the illuminator 604 may include a zone plate, for example, to improve focus of the EUV light. In some embodiments, the illuminator 604 may be configured to shape the EUV light passing therethrough in accordance with a particular pupil shape, and including for example, a dipole shape, a quadrapole shape, an annular shape, a single beam shape, a multiple beam shape, and/or a combination thereof. In some embodiments, the illuminator 604 is operable to configure the mirrors (i.e., of the illuminator 604) to provide a desired illumination to the mask 608. In one example, the mirrors of the illuminator 604 are configurable to reflect EUV light to different illumination positions. In some embodiments, a stage prior to the illuminator 604 may additionally include other configurable mirrors that may be used to direct the EUV light to different illumination positions within the mirrors of the illuminator 604. In some embodiments, the illuminator 604 is configured to provide an on-axis illumination (ONI) to the mask 608. In some embodiments, the illuminator 604 is configured to provide an off-axis illumination (OAI) to the mask 608. It should be noted that the optics employed in the EUV lithography system 504, and in particular optics used for the illuminator 604 and the projection optics 610, may include mirrors having multilayer thin-film coatings known as Bragg reflectors. By way of example, such a multilayer thin-film coating may include alternating layers of Mo and Si, which provides for high reflectivity at EUV wavelengths (e.g., about 13 nm).

As discussed above, the lithography system 504 also includes the mask stage 606 configured to secure the mask 608. Since the lithography system 504 may be housed in, and thus operate within, a high-vacuum environment, the mask stage 606 may include an electrostatic chuck (e-chuck) to secure the mask 608. The mask stage 606 may be further coupled to one or more motors that provide for translational and rotational adjustments of the mask stage 606. As with the optics of the EUV lithography system 504, the mask 608 is also reflective. As illustrated in the example of FIG. 6, light is reflected from the mask 608 and directed towards the projection optics 610, which collects the EUV light reflected from the mask 608. By way of example, the EUV light collected by the projection optics 610 (reflected from the mask 608) carries an image of the pattern defined by the mask 608. In various embodiments, the projection optics 610 provides for imaging the pattern of the mask 608 onto the substrate 616 secured on the substrate stage 618 of the lithography system 504. In particular, in various embodiments, the projection optics 610 focuses the collected EUV light and projects the EUV light onto the substrate 616 to expose an EUV resist layer deposited on the substrate 616. As described above, the projection optics 610 may include reflective optics, as used in EUV lithography systems such as the lithography system 504. In some embodiments, the illuminator 604 and the projection optics 610 are collectively referred to as an optical module of the lithography system 504.

In some embodiments, the lithography system 504 also includes a pupil phase modulator 612 to modulate an optical phase of the EUV light directed from the mask 608, such that the light has a phase distribution along a projection pupil plane 614. In some embodiments, the pupil phase modulator 612 includes a mechanism to tune the reflective mirrors of the projection optics 610 for phase modulation. For example, in some embodiments, the mirrors of the projection optics 610 are configurable to reflect the EUV light through the pupil phase modulator 612, thereby modulating the phase of the light through the projection optics 610. In some embodiments, the pupil phase modulator 612 utilizes a pupil filter placed on the projection pupil plane 614. By way of example, the pupil filter may be employed to filter out specific spatial frequency components of the EUV light reflected from the mask 608. In some embodiments, the pupil filter may serve as a phase pupil filter that modulates the phase distribution of the light directed through the projection optics 610.

As discussed above, the lithography system 504 also includes the substrate stage 618 to secure the semiconductor substrate 616 to be patterned. The substrate stage 618 may also be coupled to one or more motors that provide for translational and rotational adjustments of the substrate stage 618. In various embodiments, the semiconductor substrate 616 includes a semiconductor wafer, such as a silicon wafer, germanium wafer, silicon-germanium wafer, III-V wafer, or other type of wafer as described above or as known in the art. The semiconductor substrate 616 may be coated with a resist layer (e.g., an EUV resist layer) sensitive to EUV light. EUV resists may have stringent performance standards. For purposes of illustration, an EUV resist may be designed to provide at least around 22 nm resolution, at least around 2 nm line-width roughness (LWR), and with a sensitivity of at least around 15 mJ/cm². In the embodiments described herein, the various subsystems of the lithography system 504, including those described above, are integrated and are operable to perform lithography exposing processes including EUV lithography processes. To be sure, the lithography system 504 may further include other modules or subsystems which may be integrated with (or be coupled to) one or more of the subsystems or components described herein.

Additionally, in some embodiments, the lithography system 504 may be used to pattern one or more of the types of patterns that may be used to provide an alignment mark within a cell (e.g., such as the cell 302) of an alignment mark region (e.g., such as the alignment mark regions 202A, 202B, 202C) within a semiconductor layer and/or a resist layer. More generally, the lithography system 504 may be used to form a pattern (e.g., including a patterned resist layer) over an underlying material layer that is to be patterned. For instance, a resist layer may be formed on a material layer (of the provided substrate) that is to be patterned, and the resist layer may be exposed using the lithography system 504 according to a pattern (e.g., defined by the mask 608) and developed to provide a patterned resist layer. Prior to exposure, alignment marks on the mask 608 may be aligned to corresponding alignment marks on or within the material layer.

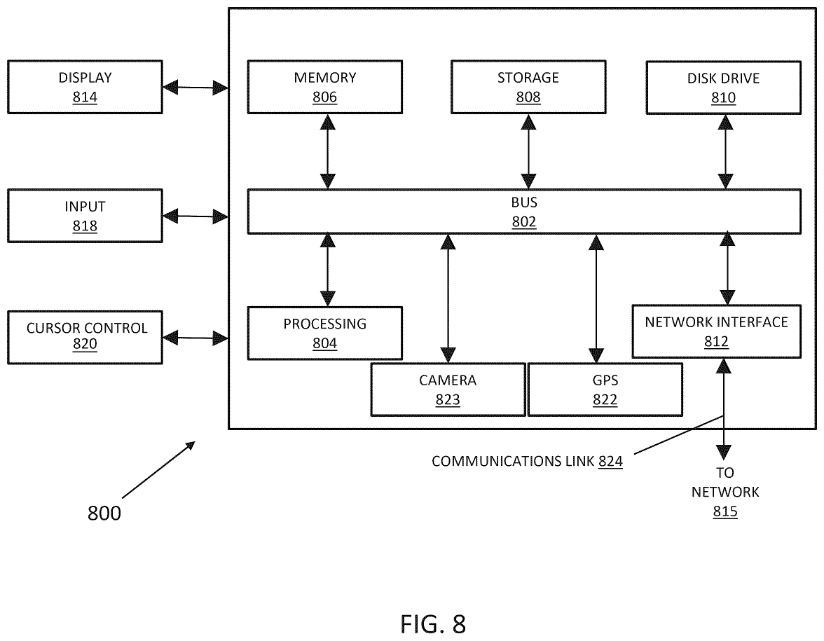

Returning to the functional flow of FIG. 5, and after development of the exposed pattern on the substrate, an after develop inspection (ADI) may be performed using one or more metrology tools 506 to provide overlay data to the lithography correction system 502. In some embodiments, the lithography correction system 502 may be implemented using any of a plurality of systems (e.g., such as a computer system 800 illustrated in FIG. 8). Further, in some cases, the lithography correction system 502 may be integrated within the lithography system 504. Thereafter, an etching process may be performed using one or more etching tools 508 so that the pattern provided by the patterned resist layer is transferred to the underlying material layer on the substrate. After the etching process, an after etch inspection (AEI) may be performed using the one or more metrology tools 506 to provide additional overlay data (e.g., such as etch-induced overlay variances) to the lithography correction system 502. In some embodiments, subsequent processing may be performed on the substrate.

Based on the overlay data collected from the ADI and/or AEI performed using the one or more metrology tools 506, adjustments may be made to the lithography system 504 by the lithography correction system 502 to improve (reduce) overlay error. In some cases, adjustments may also be made to the one or more etching tools 508. In some examples, the adjustments made to the lithography system 504 may correct for translation errors, rotational errors, and/or higher-order errors. Thus, in some embodiments, the adjustments made by the lithography correction system 502 may include adjustments to the one or more motors coupled to the mask stage 606 and/or to the substrate stage 618, adjustments to the illuminator 604, adjustments to the projection optics 610, and/or adjustments to other modules or subsystems which may be integrated with (or be coupled to) the lithography system 504. In various embodiments, patterning and etching of additional material layers may be similarly performed on some or all of subsequent material layers that are sequentially stacked on the patterned underlying material layer on the substrate. Further, inspection (e.g., to collect overlay data) and adjustments (e.g., to the lithography system 504 by the lithography correction system 502) may be performed with respect to formation of each of the subsequent material layers, as needed.

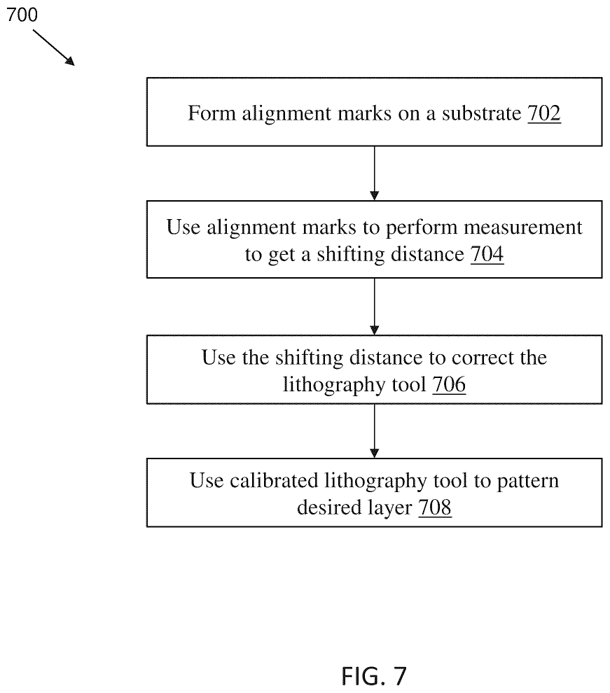

Referring now to FIG. 7, illustrated therein is a flow chart of a method 700 for reducing overlay error, in accordance with embodiments of the present disclosure. The method 700 is described with reference to FIGS. 1-3, 4A-4G, 5, and 6, discussed above. It will be understood that additional process steps may be implemented before, during, and after the method 700, and some process steps described may be replaced or eliminated in accordance with various embodiments of the method 700. It is also noted that the steps of the method 700, including any descriptions given, are merely exemplary and are not intended to be limiting beyond what is specifically recited in the claims that follow.

The method 700 begins at block 702 where alignment marks are formed on a substrate (e.g., such as the substrate 100). In various embodiments, the alignment marks may include alignment mark regions (e.g., such as the alignment mark regions 202A, 202B, 202C) formed in the scribe lines 120 and/or within chip regions 110. Further, each of the alignment mark regions formed may include a cell (e.g., such as the cell 302) having one or more of the types of patterns discussed with reference to FIGS. 4A-4G with a dummy pattern (e.g., such as the dummy pattern 306) formed adjacent to one or more sides of the cell, as previously described. Generally, formation of the alignment marks may include deposition of a resist layer over a target film (or a material layer to be patterned), exposure of the resist layer (e.g., using the lithography system 504) and etching of the target film (e.g., using the one or more etching tools 508) to form the alignment marks in the target film. In various embodiments, the alignment marks formed at block 702 may be formed prior to a target feature that is to be patterned in the target layer. In various examples, the target feature may include source/drain contacts, source/drain vias, gate vias, backside vias, interconnect lines, gate stack features, or other semiconductor device features.

After formation of the alignment marks, the method 700 proceeds to block 704 where the alignment marks are used to perform a measurement to get a shifting distance. The shifting distance (or offset distance) may be extracted from, or provided by, overlay data that may be measured by the one or more metrology tools 506. In some embodiments, the shifting distance may be described as a distance between an ideal (or target) position and an actual position of the alignment marks patterned on the substrate. The overlay data and/or the shifting distance may be provided to the lithography correction system 502 for performing adjustments to the lithography system 504.

After determining the shifting distance, the method 700 proceeds to block 706 where the overlay data and/or the shifting distance is used by the lithography correction system 502 to correct, or provide adjustments to, the lithography system 504. As discussed above, the adjustments made to the lithography system 504 by the lithography correction system 502 may correct for translation errors, rotational errors, and/or higher-order errors. Thus, in some embodiments, the adjustments made by the lithography correction system 502 may include adjustments to the one or more motors coupled to the mask stage 606 and/or to the substrate stage 618, adjustments to the illuminator 604, adjustments to the projection optics 610, and/or adjustments to other modules or subsystems which may be integrated with (or be coupled to) the lithography system 504. In particular, and because of the high density of alignment marks provided, there will be an increased amount of overlay raw data provided to the lithography correction system 502, and the adjustments made to the lithography system 504 will be highly accurate and greatly reduce overlay error.

Once the adjustments are made to the lithography system 504 (or once the lithography system 504 is calibrated), the method 700 proceeds to block 708 where the lithography tool 504 is used to pattern the target feature within the target layer. As noted, the target feature may include source/drain contacts, source/drain vias, gate vias, backside vias, interconnect lines, gate stack features, or other semiconductor device features. In accordance with embodiments of the present disclosure, and by calibrating the lithography system 504 by utilizing a high density of alignment marks, there will be substantially little to no shift between a target feature and an underlying feature to which the target feature is to be aligned. For instance, in various embodiments, the overlay error may be reduced by about 50% in comparison to at least some existing processes, and the 3-standard deviation limit of overlay errors may be in a range of about 10-10.6 nm.

As noted above, the lithography correction system 502 may be implemented using a computer system 800, such as illustrated in FIG. 8. In accordance with various embodiments of the present disclosure, computer system 800, such as a computer and/or a network server, includes a bus 802 or other communication mechanism for communicating information, which interconnects subsystems and components, such as a processing component 804 (e.g., processor, micro-controller, digital signal processor (DSP), etc.), a system memory component 806 (e.g., RAM), a static storage component 808 (e.g., ROM), a disk drive component 810 (e.g., magnetic or optical), a network interface component 812 (e.g., modem or Ethernet card), a display component 814 (e.g., CRT or LCD), an input component 818 (e.g., keyboard, keypad, or virtual keyboard), a cursor control component 820 (e.g., mouse, pointer, or trackball), a location determination component 822 (e.g., a Global Positioning System (GPS) device as illustrated, a cell tower triangulation device, and/or a variety of other location determination devices known in the art), and/or a camera component 823. In one implementation, the disk drive component 810 may comprise a database having one or more disk drive components.

In accordance with embodiments of the present disclosure, the computer system 800 performs specific operations by the processor 804 executing one or more sequences of instructions contained in the memory component 806, such as described herein with respect to the IC manufacturing system 500 and the method 700. Such instructions may be read into the system memory component 806 from another computer readable medium, such as the static storage component 808 or the disk drive component 810. In other embodiments, hard-wired circuitry may be used in place of or in combination with software instructions to implement the present disclosure.

Logic may be encoded in a computer readable medium, which may refer to any medium that participates in providing instructions to the processor 804 for execution. Such a medium may take many forms, including but not limited to, non-volatile media, volatile media, and transmission media. In one embodiment, the computer readable medium is non-transitory. In various implementations, non-volatile media includes optical or magnetic disks, such as the disk drive component 810, volatile media includes dynamic memory, such as the system memory component 806, and transmission media includes coaxial cables, copper wire, and fiber optics, including wires that comprise the bus 802. In one example, transmission media may take the form of acoustic or light waves, such as those generated during radio wave and infrared data communications.

Some common forms of computer readable media includes, for example, floppy disk, flexible disk, hard disk, magnetic tape, any other magnetic medium, CD-ROM, any other optical medium, punch cards, paper tape, any other physical medium with patterns of holes, RAM, PROM, EPROM, FLASH-EPROM, any other memory chip or cartridge, carrier wave, or any other medium from which a computer is adapted to read. In one embodiment, the computer readable media is non-transitory.

In various embodiments of the present disclosure, execution of instruction sequences to practice the present disclosure may be performed by the computer system 800. In various other embodiments of the present disclosure, a plurality of the computer systems 800 coupled by a communication link 824 to a network 815 (e.g., such as a LAN, WLAN, PTSN, and/or various other wired or wireless networks, including telecommunications, mobile, and cellular phone networks) may perform instruction sequences to practice the present disclosure in coordination with one another.

The computer system 800 may transmit and receive messages, data, information and instructions, including one or more programs (i.e., application code) through the communication link 824 and the network interface component 812. The network interface component 812 may include an antenna, either separate or integrated, to enable transmission and reception via the communication link 824. Received program code may be executed by processor 804 as received and/or stored in disk drive component 810 or some other non-volatile storage component for execution.

Where applicable, various embodiments provided by the present disclosure may be implemented using hardware, software, or combinations of hardware and software. Also, where applicable, the various hardware components and/or software components set forth herein may be combined into composite components comprising software, hardware, and/or both without departing from the scope of the present disclosure. Where applicable, the various hardware components and/or software components set forth herein may be separated into sub-components comprising software, hardware, or both without departing from the scope of the present disclosure. In addition, where applicable, it is contemplated that software components may be implemented as hardware components and vice-versa.

Software, in accordance with the present disclosure, such as program code and/or data, may be stored on one or more computer readable mediums. It is also contemplated that software identified herein may be implemented using one or more general purpose or specific purpose computers and/or computer systems, networked and/or otherwise. Where applicable, the ordering of various steps described herein may be changed, combined into composite steps, and/or separated into sub-steps to provide features described herein.

The various embodiments described herein offer several advantages over the existing art. It will be understood that not all advantages have been necessarily discussed herein, no particular advantage is required for all embodiments, and other embodiments may offer different advantages. For example, embodiments discussed herein provide a semiconductor device, and related method, for increasing an amount of overlay raw data that is retrieved, thereby mitigating loss of overlay error information, and reducing overlay error by ensuring that the positional adjustment of the photolithography tool is more accurate. In various embodiments, the increased amount of overlay raw data is provided by the use of a high density of alignment marks. In particular, and in various embodiments, the alignment marks are distributed both in wafer scribe lines (e.g., between chips) and within individual chips themselves. In some embodiments, the exact positions and/or number of the alignment marks within the chips may vary based on a particular layer being patterned. Furthermore, in some embodiments, different types of cells, having patterns with a variety of duty ratios, may be used to define each alignment mark of the plurality of alignment marks.

Thus, one of the embodiments of the present disclosure described a semiconductor device including a substrate having a plurality of chip regions. In some embodiments, the semiconductor device further includes a plurality of scribe lines interposing the plurality of chip regions. In some examples, the semiconductor device further includes a first plurality of alignment mark regions distributed within the plurality of scribe lines. In some embodiments, the semiconductor device further includes a second plurality of alignment mark regions distributed within each of the plurality of chip regions.

In another of the embodiments, discussed is an IC manufacturing system including a lithography system, one or more metrology tools, and a lithography correction system. In some embodiments, the lithography system is configured to form a pattern on a substrate that includes a plurality of chip regions, where the pattern includes a plurality of alignment mark regions distributed within each of the plurality of chip regions and within scribe lines that interpose the plurality of chip regions. In some cases, the one or more metrology tools is configured to inspect the pattern to provide overlay data. In some embodiments, the lithography correction system is coupled to receive the overlay data from the one or more metrology tools. In various examples, the lithography correction system is configured to make one or more adjustments to the lithography system based on the received overlay data.

In yet another of the embodiments, discussed is a method that includes forming, on a substrate having a plurality of chip regions, a first plurality of alignment marks within the each of the plurality of chip regions and a second plurality of alignment marks within scribe lines interposing the plurality of chip regions. In some embodiments, the method further includes determining an offset distance from overlay data corresponding to the first and second plurality of alignment marks. In some examples, the method further includes providing, based on the determined offset distance, adjustments to a lithography system. In some embodiments, the method further includes after providing the adjustments to the lithography system, performing a photolithography process to pattern a target feature on the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device layout, comprising:
a chip region;
a scribe line adjacent to at least one side of the chip region;
two or more in-chip alignment mark regions disposed in one or more quadrants of the chip region;
a first alignment mark region disposed at one or more exposure field corners outside the chip region; and
two or more second alignment mark regions distributed within the scribe line adjacent to the at least one side of the chip region;
wherein the two or more in-chip alignment mark regions define a first pattern, wherein the first alignment mark region defines a second pattern, wherein the two or more second alignment mark regions define a third pattern; and
wherein the first pattern is different than at least one of the second pattern and the third pattern.

2. The semiconductor device layout of claim 1, wherein the two or more in-chip alignment mark regions are disposed in each quadrant of the chip region.

3. The semiconductor device layout of claim 1, wherein the first alignment mark region is disposed at each exposure field corner outside the chip region.

4. The semiconductor device layout of claim 1, wherein the two or more second alignment mark regions are distributed within additional scribe lines adjacent to additional sides of the chip region.

5. The semiconductor device layout of claim 1, wherein each of the two or more in-chip alignment mark regions include a first cell that defines the first pattern, the first alignment mark region includes a second cell that defines the second pattern, and the two or more second alignment mark regions include a third cell that defines the third pattern.

6. The semiconductor device layout of claim 5, wherein a dummy pattern is disposed adjacent to one or more sides of one or more of the first cell, the second cell, and the third cell.

7. The semiconductor device layout of claim 1, wherein at least one of the first pattern, the second pattern, and the third pattern includes an array of patterns having a constant duty ratio.

8. The semiconductor device layout of claim 1, wherein at least one of the first pattern, the second pattern, and the third pattern includes an array of patterns having a varying duty ratio.

9. The semiconductor device layout of claim 1, wherein at least one of the first pattern, the second pattern, and the third pattern includes an array of patterns having a first duty ratio along a first direction and a second duty ratio along a second direction different than the first direction.

10. An integrated circuit (IC) manufacturing system, comprising:
a lithography system configured to form a patterned resist layer on an underlying layer, wherein the patterned resist layer includes a first plurality of alignment mark regions uniformly distributed across plural quadrants of a chip region, a second plurality of alignment mark regions distributed within scribe lines adjacent to the chip region, and a third plurality of alignment mark regions disposed at multiple exposure field corners outside the chip region, wherein the first, second, and third plurality of alignment mark regions define respective first, second, and third patterns, and wherein the first pattern is different from at least one of the second pattern and the third pattern;
a first metrology tool configured to perform an after develop inspection (ADI) to the patterned resist layer to generate overlay data; and
a lithography correction system configured to make an adjustment to the lithography system based on the overlay data.

11. The IC manufacturing system of claim 10, wherein the lithography correction system is integrated within the lithography system.

12. The IC manufacturing system of claim 10, further comprising:
an etching tool configured to etch the underlying layer through the patterned resist layer; and
a second metrology tool configured to perform an after etch inspection (AEI) to the etched underlying layer to generate additional overlay data;
wherein the lithography correction system is further configured to make the adjustment to the lithography system based on the additional overlay data.

13. The IC manufacturing system of claim 10, wherein the adjustment is configured to correct for one or more of translation errors, rotational errors, and higher-order errors.

14. The IC manufacturing system of claim 10, wherein the adjustment includes one or more of adjustments to motors coupled to a mask stage or a substrate stage of the lithography system, adjustments to an illuminator of the lithography system, and adjustments to projection optics of the lithography system.

15. The IC manufacturing system of claim 10, wherein at least one of the first pattern, the second pattern, and the third pattern includes an array of patterns having a varying duty ratio.

16. The IC manufacturing system of claim 10, wherein at least one of the first pattern, the second pattern, and the third pattern includes an array of patterns having a first duty ratio along a first direction and a second duty ratio along a second direction different than the first direction.

17. A method, comprising:
forming a patterned resist layer on an underlying layer, the patterned resist layer including a first plurality of alignment mark regions distributed across multiple quadrants of a chip region, a second plurality of alignment mark regions distributed within scribe lines adjacent to the chip region, and a third plurality of alignment mark regions disposed at multiple exposure field corners outside the chip region, wherein the first, second, and third plurality of alignment mark regions define respective first, second, and third patterns, and wherein the first pattern is different from at least one of the second pattern and the third patterns;
determining a shifting distance from overlay data corresponding to the first, second, and third plurality of alignment marks;
providing one or more adjustments to a lithography system based on the shifting distance; and
after providing the one or more adjustments, performing a photolithography process to pattern a target feature on the underlying layer.

18. The method of claim 17, wherein the first plurality of alignment mark regions includes two or more alignment mark regions disposed in each quadrant of the chip region.

19. The method of claim 17, wherein at least one of the first pattern, the second pattern, and the third pattern includes an array of patterns having a varying duty ratio.

20. The method of claim 17, wherein at least one of the first pattern, the second pattern, and the third pattern includes an array of patterns having a first duty ratio along a first direction and a second duty ratio along a second direction different than the first direction.
